(19) United States
(12) Patent Application Publication
(10) Pub. No.: US 2026/0262424 A1
(43) Pub. Date: Sep. 3, 2026

(54) LIGHT EMITTING DISPLAY APPARATUS

(71) Applicant: LG Display Co., Ltd., Seoul (KR)

(72) Inventors: KyungEon Lee, Gyeonggi-do (KR); Sungman Han, Gyeonggi-do (KR)

(21) Appl. No.: 19/551,724

(22) Filed: Feb. 27, 2026

(30) Foreign Application Priority Data
Feb. 28, 2025 (KR) 10-2025-0026719

(51) Int. Cl. H10K 59/80; H10K 59/38

(52) U.S. Cl. CPC H10K 59/878; H10K 59/38

(57) ABSTRACT

A light emitting display apparatus may include a substrate including a plurality of subpixels, the substrate having an emission area and a non-emission area, a pixel circuit disposed in the non-emission area of the substrate, at least one insulating layer disposed on the pixel circuit, a first overcoat layer disposed on the at least one insulating layer, the first overcoat layer having a sloped side surface and configured with a positive taper structure in which a width of the first overcoat layer increases toward the substrate, a reflective layer formed on the sloped side surface of the first overcoat layer, a second overcoat layer contacting the first overcoat layer and covering the reflective layer, and a light emitting device disposed on the first overcoat layer and the second overcoat layer and overlapping the emission area.

### CROSS-REFERENCE TO RELATED APPLICATION

Pursuant to 35 U.S.C. § 119(a), this application claims the benefit of an earlier filing date and right of priority to Korean Patent Application No. 10-2025-0026719, filed in Republic of Korea on February 28, 2025, the entire content of which is incorporated herein by reference for all purposes.

### TECHNICAL FIELD

The present disclosure relates to a light emitting display apparatus.

### BACKGROUND

With the advancement of the information age, the demand for a display apparatus for displaying an image has increased in various forms. Therefore, various types of display apparatuses, such as a liquid crystal display (LCD) apparatus, an organic light emitting display (OLED) apparatus, a micro light emitting diode (micro LED) display apparatus, and a quantum dot display (QD) apparatus, have been recently used.

Among light emitting display apparatuses, an organic light emitting display apparatus is a self-luminance type that injects holes and electrons into an emission layer from an anode electrode for hole injection and a cathode electrode for electron injection, respectively, so that excitons formed by the recombination of the injected holes and electrons emit light as they fall from an excited state to a ground state, thereby displaying an image.

### SUMMARY

According to an aspect of the present disclosure, a light emitting display apparatus may include a substrate including a plurality of subpixels, the substrate having an emission area and a non-emission area, a pixel circuit disposed in the non-emission area of the substrate, at least one insulating layer disposed on the pixel circuit, a first overcoat layer disposed on the at least one insulating layer, the first overcoat layer having a sloped side surface and configured with a positive taper structure in which a width of the first overcoat layer increases toward the substrate, a reflective layer formed on the sloped side surface of the first overcoat layer, a second overcoat layer contacting the first overcoat layer and covering the reflective layer, and a light emitting device disposed on the first overcoat layer and the second overcoat layer and overlapping the emission area.

Implementations of the present disclosure can provide various technical effects, some examples of which are described below.

According to one or more implementations of the present disclosure, a light emitting display apparatus capable of improving light extraction efficiency of light emitted from a light emitting device can be provided.

The light emitting display apparatus according to one or more implementations of the present disclosure can improve light extraction efficiency, thereby reducing power consumption and enabling low-power driving, and may provide an ESG (Environmental, Social, and Governance) effect of reducing production energy.

The effects of the present disclosure are not limited to the aforesaid, but other effects not described herein will be clearly understood by those skilled in the art from the following descriptions.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate implementations of the disclosure, and together with the description serve to explain various principles and examples of the disclosure.

FIG. 1 illustrates an example of a light emitting display apparatus according to an implementation of the present disclosure.

FIG. 2 illustrates an example of a circuit diagram of a subpixel of a light emitting display apparatus according to an implementation of the present disclosure.

FIG. 3 illustrates an example of a plurality of subpixels in a display panel according to one implementation of the present disclosure.

FIG. 4 is a cross-sectional view taken along line I–I′ in FIG. 3 according to one implementation of the present disclosure.

FIG. 5 illustrates an example of an A region shown in FIG. 4 according to one implementation of the present disclosure.

FIG. 6 illustrates another example of an A region shown in FIG. 4 according to one implementation of the present disclosure.

FIG. 7 illustrates an example of a plurality of subpixels in a display panel according to another implementation of the present disclosure.

FIG. 8 illustrates an example of a plurality of subpixels in a display panel according to another implementation of the present disclosure.

FIGS. 9 to 16 illustrate an example of a method of manufacturing a display panel according to one implementation of the present disclosure.

FIGS. 17 to 19 illustrate an example of a method of manufacturing a display panel according to another implementation of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

In a light emitting display apparatus, a portion of light emitted from a light emitting device may fail to be emitted to the outside due to total reflection occurring at interfaces or between layers inside a display panel. This may cause a problem of reduced light extraction efficiency of the light emitting display apparatus.

One or more implementations of the present disclosure can provide a light emitting display apparatus capable of improving light extraction efficiency of light emitted from a light emitting device.

Advantages and features of the present disclosure, and implementation methods thereof, are clarified through various example implementations described with reference to the accompanying drawings. The present disclosure may, however, be embodied in different forms and should not be construed as limited to the implementations set forth herein. Rather, these implementations are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), ratios, angles, numbers, and the like disclosed herein, including those illustrated in the drawings, are merely examples. Thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

Where the term “comprise,” “have,” “include,” “contain,” “constitute,” “made of,” “formed of,” or the like is used with respect to one or more elements, one or more other elements may be added unless a more limiting term, such as “only” or the like, is used. The terms used in the present disclosure are merely used in order to describe example implementations and are not intended to limit the scope of the present disclosure. The terms of a singular form may include plural forms, and vice versa, unless the context clearly indicates otherwise.

In construing an element, the element is construed as including an error range although there is no explicit description thereof.

In describing a positional relationship, for example, where the positional order is described as “on,” “above,” “below,” “beneath”, and “next,” the case of no contact therebetween may be included, unless a more limiting term like “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, where the temporal order is described as “after,” “subsequent,” “next,” and “before,” a case which is not continuous may be included, unless a more limiting term like “just” or “direct” is used.

It will be understood that, although the terms “first,” “second,” etc., may be used herein to describe various elements, these elements should not be limited by these terms. These terms are only used to refer to one element separately from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various implementations of the present disclosure may be partially or entirely coupled to or combined with each other, may be technically associated with each other, and may be variously inter-operated, linked or driven together. The implementations of the present disclosure may be implemented or carried out independently of each other, or may be implemented or carried out together in a co-dependent or related relationship. In one or more aspects, the components of each apparatus according to various implementations of the present disclosure may operatively be coupled and configured.

In the following description, various example implementations of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness. Thus, implementations of the present disclosure are not limited to a scale, dimension, size, and thickness illustrated in the drawings.

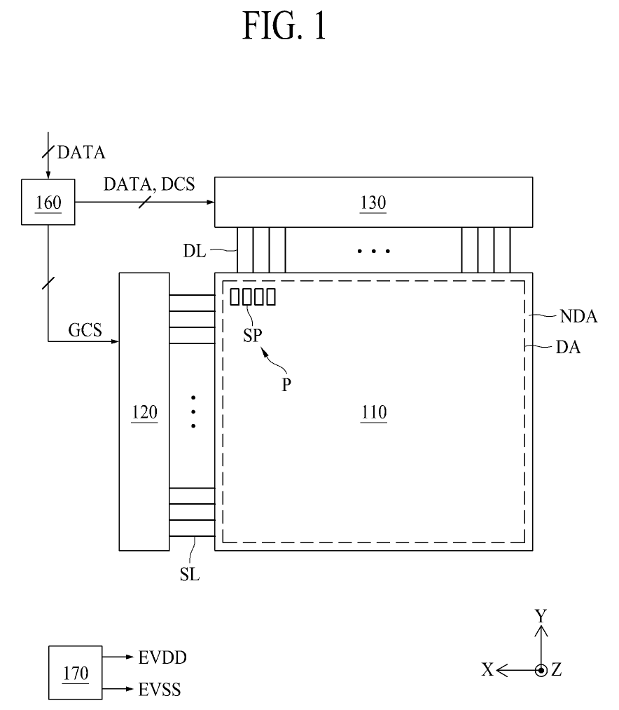

FIG. 1 illustrates a light emitting display apparatus according to an implementation of the present disclosure.

Hereinafter, an X-axis represents a direction parallel to a scan line (or a gate line), a Y-axis represents a direction parallel to a data line, and a Z-axis represents a height direction of the light emitting display apparatus.

A light emitting display apparatus according to an implementation of the present disclosure is implemented as an organic light emitting display apparatus, but may also be implemented as a liquid crystal display apparatus, a quantum dot light emitting diode display apparatus, or an electrophoretic display apparatus.

As shown in FIG. 1, the light emitting display apparatus according to an implementation of the present disclosure may include a display panel 110, a scan driver (or a gate driver) 120 embedded in the display panel 110, a data driver 130 connected to the display panel 110, a timing controller 160 configured to control the scan driver 120 and the data driver 130, and a power circuit 170.

The display panel 110 includes a display area DA and a non-display area NDA surrounding the display area DA. The display panel 110 includes pixels P provided in the display area DA to display an image. Each of the pixels P may include a plurality of subpixels SP. The structure of the subpixel SP may be variously changed according to the type of the light emitting display apparatus. For example, the subpixels SP may be formed in a top emission type, a bottom emission type, or a dual emission type according to the structure of the subpixel SP. The subpixels SP indicate a unit provided with a color filter of specific color or capable of emitting light of specific color itself without providing a color filter. The subpixels SP may have one or more other light-emitting areas according to light-emitting characteristics. For example, the plurality of subpixels SP may be arranged in a stripe shape or a quad shape, but implementations of the present disclosure are not limited thereto. The color type, arrangement type, arrangement order, and the like of the subpixels SP may be configured in various forms according to the light-emitting characteristics, lifespan of the apparatus, spec of the apparatus, and the like.

The display panel 110 may include data lines DL and scan lines (or gate lines) SL connected to the subpixels SP. The data lines DL may be arranged to cross the scan lines SL. Each of the subpixels SP of the display panel 110 may be connected to any one of the data lines DL and any one of the scan lines SL. The data lines DL may supply a data voltage supplied from the data driver 130 to each of the subpixels SP. The scan lines SL may supply a scan signal supplied from the scan driver 120 to each of the subpixels SP.

Each of the subpixels SP is turned-on by the scan signal. When the data voltage of the data line DL is supplied to a gate electrode of a driving transistor, a light emitting element may emit light according to a drain-to-source current of the driving transistor. The scan driver 120 may receive a scan control signal GCS from the timing controller 160. The scan driver 120 may supply the scan signals or emission control signal to the scan lines SL by using the scan control signal GCS.

The scan driver 120 may be configured in a gate driver in panel GIP manner in the non-display area NDA outside one side or both sides of the display area DA. Alternatively, the scan driver 120 may be manufactured as a driving chip, mounted on a flexible film, and attached to the non-display area NDA outside one side or both sides of the display area DA in a tape automated bonding TAB manner.

The data driver 130 may receive digital video data DATA and a data control signal DCS from the timing controller 160. The data driver 130 converts the digital video data DATA into analog positive/negative data voltages by using the data control signal DCS and supplies the analog positive/negative data voltages to the data lines DL.

The timing controller 160 receives digital video data DATA and timing signals from a host system. The timing signals may include a vertical synchronization signal, a horizontal synchronization signal, a data enable signal, a dot clock, and the like. The vertical synchronization signal is a signal defining one frame period. The horizontal synchronization signal is a signal defining one horizontal period for supplying the data voltages to the pixels of one horizontal line of the display panel 110. The data enable signal defines a period in which valid data is input. The dot clock is a signal repeated at a predetermined short period.

The timing controller 160 may generate the data control signal DCS for controlling an operation timing of the data driver 130 and the scan control signal GCS for controlling an operation timing of the scan driver 120 based on the timing signals. The timing controller 160 may output the scan control signal GCS to the scan driver 120 to control the scan driver 120 and output the digital video data DATA and data control signal DCS to the data driver 130 to control the data driver 130.

The power circuit 170 may generate and supply a plurality of driving voltages for an operation of all circuit configurations of the light emitting display apparatus by using an input voltage. The power circuit 170 may generate a first power source voltage (or pixel power voltage) EVDD, a second power supply voltage (or common power voltage) EVSS and an initialization voltage (or reference voltage) Vref and supply the generated voltages to the display panel 110. The power circuit 170 may generate and supply various driving voltages for operations of the scan driver 120, the data driver 130, and the timing controller 160.

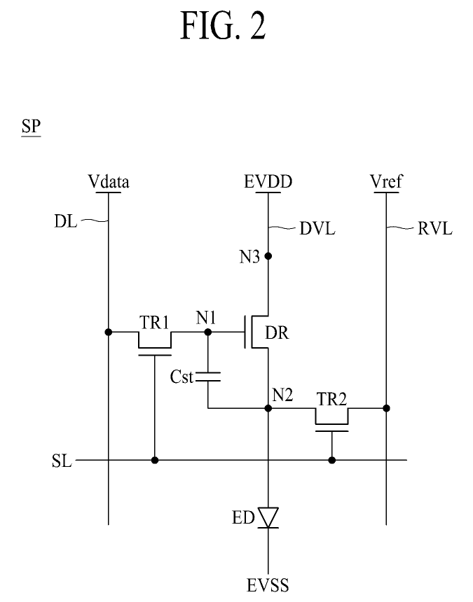

FIG. 2 illustrates a circuit diagram of a subpixel of a light emitting display apparatus according to an implementation of the present disclosure.

As shown in FIG. 2, each of pixels P includes the plurality of subpixels SP constituting a unit pixel. In each of the plurality of subpixels SP, there are a pixel circuit having 3T(Transistor)1C(Capacitor) including the driving transistor DR, the first switching transistor TR1, the second switching transistor TR2 and the storage capacitor Cst, and the light emitting device ED, but not limited thereto. Each subpixel SP may further include a compensation circuit. In this case, the subpixel SP may have various structures such as 3T2C, 4T1C, 4T2C, 5T1C, 5T2C, 6T1C, 6T2C, 7T1C, and 7T2C.

At least one thin film transistor DR, TR1 and TR2 of each subpixel SP may include a gate electrode, a source electrode, and a drain electrode. Since the source electrode and the drain electrode may be changed according to a voltage and a current direction applied to the gate electrode without being fixed, any one of the source electrode and the drain electrode may be represented as a first electrode, and the other may be represented as a second electrode. The at least one transistor DR, TR1, and TR2 may use at least one of polysilicon semiconductor, amorphous silicon semiconductor, and oxide semiconductor. The transistors DR, TR1, and TR2 may be P-type or N-type, or P-type and N-type may be interchangeably used.

The driving transistor DR may be a transistor for driving a light emitting device ED, and may include a first node N1 to which a data voltage Vdata is applied, a second node N2 connected to a pixel electrode (a first electrode or an anode electrode) of the light emitting device ED, and a third node N3 connected to a first power voltage line (or a pixel power voltage line) DVL to which a first power voltage (or a pixel power voltage) EVDD is applied. For example, the driving transistor DR may generate a data current from the first power voltage EVDD supplied through the first power voltage line DVL and supply the data current to the first electrode of the light emitting device ED.

The first switching transistor TR1 may serve to supply the data voltage Vdata supplied from the data line DL to the first node N1 of the driving transistor DR. The second switching transistor TR2 may serve to supply the reference voltage Vref supplied from the reference voltage line RVL to the second node N2 of the driving transistor DR or may output a voltage of the second node N2 of the driving transistor DR. The storage capacitor Cst may be connected between the first node N1 and the second node N2 of the driving transistor DR. The storage capacitor Cst may serve to maintain the data voltage Vdata supplied to the driving transistor DR for one frame period, but implementations of the present disclosure are not limited thereto.

The light emitting device ED may include the pixel electrode (also referred to herein as a first electrode or anode electrode) connected to the second node N2 of the driving transistor DR, and a common electrode (also referred to herein as a second electrode or a cathode electrode) CE connected to a second power voltage line CVL. The light emitting device ED may emit light from an emission layer (also referred to herein as an organic emission layer) between the first electrode and the second electrode in response to a driving current generated by the driving transistor DR. The pixel electrode of the light emitting device ED may be an independent electrode for each light emitting device, and the common electrode and the emission layer of the light emitting device ED may be common layers shared by all light emitting devices, but implementations of the present disclosure are not limited thereto. According to an implementation of the present disclosure, the light emitting device ED may include two or more emission layers, and the two or more emission layers may be configured in a tandem structure in which the emission layers are vertically stacked, but implementations of the present disclosure are not limited thereto.

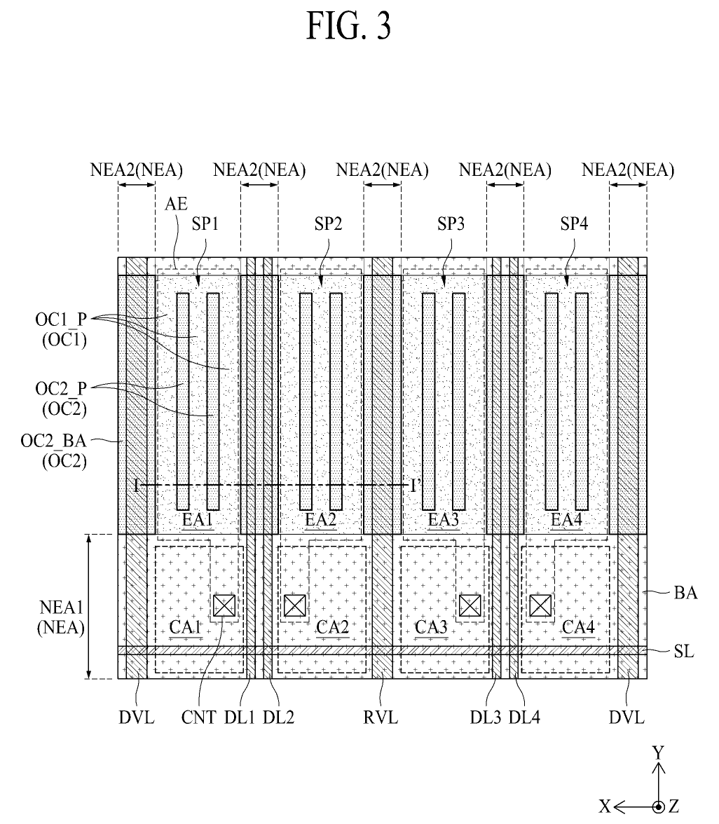

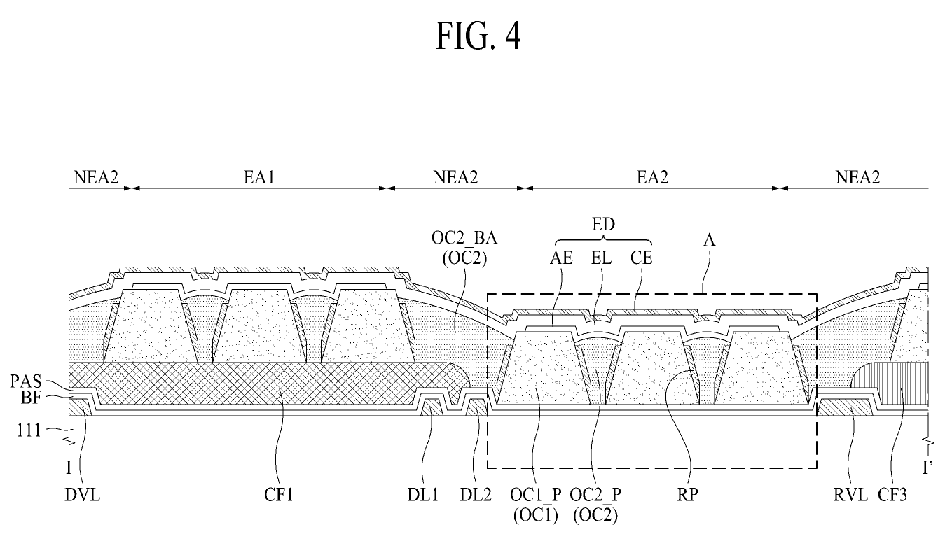

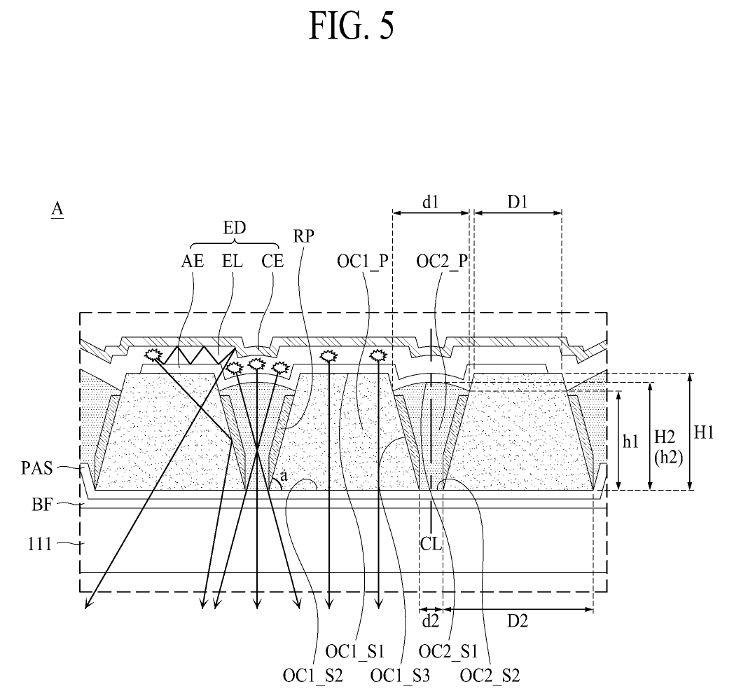

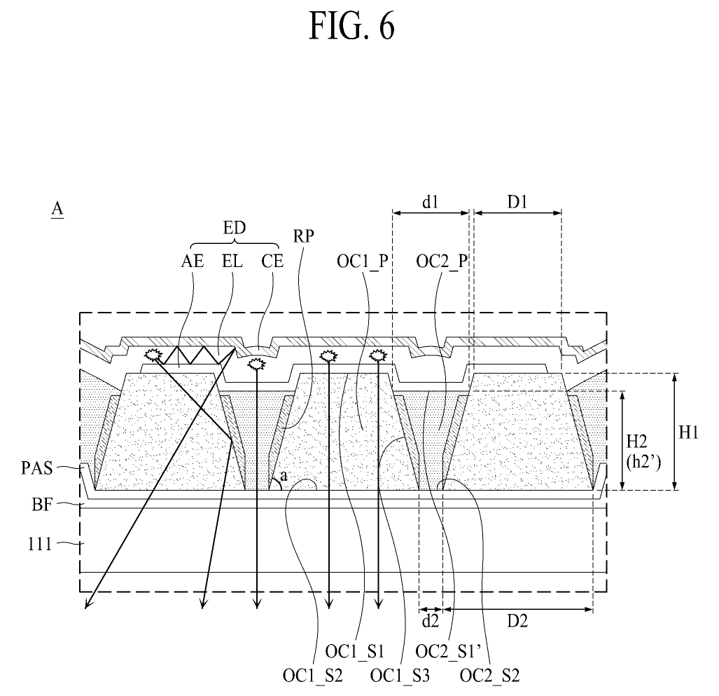

FIG. 3 illustrates a plurality of subpixels in a display panel according to one implementation of the present disclosure. FIG. 4 is a cross-sectional view taken along line I–I′ in FIG. 3 according to one implementation of the present disclosure. FIG. 5 illustrates an example of an A region shown in FIG. 4 according to one implementation of the present disclosure. FIG. 6 illustrates another example of an A region shown in FIG. 4 according to one implementation of the present disclosure.

As shown in FIGS. 3 to 6, the display panel 110 according to one implementation of the present disclosure may be configured as a top-emission type, a bottom-emission type, or a dual-emission type. For example, the display panel 110 may be implemented as the bottom-emission type, but implementations of the present disclosure are not limited thereto.

The display panel 110 according to one implementation of the present disclosure may include a plurality of subpixels SP1, SP2, SP3, and SP4, a plurality of data lines DL1, DL2, DL3, and DL4, at least one scan line (or gate line) SL, a first power voltage line DVL, a reference voltage line RVL, a plurality of pixel circuits CA1, CA2, CA3, and CA4, at least one color filter CF1, CF3, and CF4, a first overcoat layer OC1, a second overcoat layer OC2, and a reflective layer RP.

The plurality of subpixels SP1, SP2, SP3, and SP4 may be unit pixels representing different colors. The plurality of subpixels SP1, SP2, SP3, and SP4 may be arranged in a stripe pattern aligned in the first direction (or X-axis direction) or the second direction (or Y-axis direction). For example, the plurality of subpixels SP1, SP2, SP3, and SP4 may be arranged in the first direction (or X-axis direction), but implementations of the present disclosure are not limited thereto, and the arrangement order or layout pattern may be variously modified.

The plurality of subpixels SP1, SP2, SP3, and SP4 may include emission areas EA1, EA2, EA3, and EA4 in which light is emitted by light emitting devices ED each including a pixel electrode AE, an emission layer EL, and a common electrode CE, and a non-emission area NEA. For example, the non-emission area NEA may include a first non-emission area NEA1 in which pixel circuits CA1, CA2, CA3, and CA4 are disposed, and a second non-emission area NEA2 between adjacent subpixels SP1, SP2, SP3, and SP4. For example, the pixel circuits CA1, CA2, CA3, and CA4 of the respective subpixels SP1, SP2, SP3, and SP4 may include at least one thin film transistor DR, TR1, or TR2 and a storage capacitor Cst, but implementations of the present disclosure are not limited thereto.

The display panel 110 according to one implementation of the present disclosure may be implemented as a bottom-emission type, and the emission areas EA1, EA2, EA3, and EA4 of the respective subpixels SP1, SP2, SP3, and SP4 and the first non-emission areas NEA1 in which the pixel circuits CA1, CA2, CA3, and CA4 are disposed may not overlap each other or may overlap at least in part. For example, the emission areas EA1, EA2, EA3, and EA4 may be disposed on an upper side in the second direction (or Y-axis direction), and the first non-emission area NEA1 may be disposed on a lower side in the second direction, but implementations of the present disclosure are not limited thereto.

In the first non-emission area NEA1, at least one scan line SL extending in the first direction (or X-axis direction) may be disposed, and in the second non-emission area NEA2, at least one voltage signal line extending in the second direction (or Y-axis direction) may be disposed. For example, the at least one voltage signal line may include the plurality of data lines DL1, DL2, DL3, and DL4, the at least one reference voltage line RVL, and the at least one first power voltage line (or driving power voltage line) DVL.

The at least one scan line (or gate line) SL may be disposed to overlap the first non-emission area NEA1 in which the pixel circuits CA1, CA2, CA3, and CA4 are disposed. The at least one scan line SL may extend in the first direction (or X-axis direction) to cross the first non-emission area NEA1. The at least one scan line SL may supply a scan signal to at least one thin film transistor TR1 or TR2 included in the pixel circuits CA1, CA2, CA3, and CA4. For example, the at least one scan line SL may be formed of the same material in the same layer as a gate electrode of at least one thin film transistor DR, TR1, or TR2 disposed in the pixel circuits CA1, CA2, CA3, and CA4. For example, the at least one scan line SL may include a plurality of scan lines SL configured to apply separate scan signals to first and second switching transistors TR1 and TR2 of the pixel circuits CA1, CA2, CA3, and CA4, but implementations of the present disclosure are not limited thereto.

The plurality of data lines DL1, DL2, DL3, and DL4 may be disposed to correspond to the respective subpixels SP1, SP2, SP3, and SP4. The plurality of data lines DL1, DL2, DL3, and DL4 may be disposed between the plurality of subpixels SP1, SP2, SP3, and SP4. For example, the plurality of data lines DL1, DL2, DL3, and DL4 may be disposed to overlap the second non-emission area NEA2 between adjacent subpixels SP1, SP2, SP3, and SP4. The plurality of data lines DL1, DL2, DL3, and DL4 may extend in the second direction (or Y-axis direction) in the second non-emission area NEA2.

The at least one first power voltage line (or driving power voltage line) DVL may be disposed to correspond to the plurality of subpixels SP1, SP2, SP3, and SP4. The at least one first power voltage line DVL may be disposed on the left side or the right side of the plurality of subpixels SP1, SP2, SP3, and SP4. For example, the at least one first power voltage line DVL may be disposed on the left side of the first subpixel SP1 and may be disposed to overlap the second non-emission area NEA2 between the first subpixel SP1 and the fourth subpixel SP4 of another adjacent pixel P. In addition, the at least one first power voltage line DVL may be disposed on the right side of the fourth subpixel SP4 and may be disposed to overlap the second non-emission area NEA2 between the fourth subpixel SP4 and the first subpixel SP1 of another adjacent pixel P. The at least one first power voltage line DVL may extend in the second direction (or Y-axis direction) in the second non-emission area NEA2 between adjacent pixels P.

The reference voltage line RVL may be disposed to correspond to the plurality of subpixels SP1, SP2, SP3, and SP4. The reference voltage line RVL may be disposed within the plurality of subpixels SP1, SP2, SP3, and SP4. The reference voltage line RVL may be disposed between the second subpixel SP2 and the third subpixel SP3. The reference voltage line RVL may extend in the second direction (or Y-axis direction) in the second non-emission area NEA2 between the second subpixel SP2 and the third subpixel SP3.

The first non-emission area NEA1 may further include a bank portion BA that covers edges of the pixel electrodes AE of the respective subpixels SP1, SP2, SP3, and SP4. The bank portion BA may be disposed between the pixel electrodes AE and the emission layer EL of the respective subpixels SP1, SP2, SP3, and SP4. For example, the bank portion BA may be configured to cover a contact portion CNT where the pixel electrodes AE of the respective subpixels SP1, SP2, SP3, and SP4 are electrically connected to the second nodes (or source electrodes) N2 of the driving transistors DR of respective pixel circuits CA1, CA2, CA3, and CA4. According to one implementation of the present disclosure, the second overcoat layer OC2 may be disposed in the second non-emission area NEA2 between the respective subpixels SP1, SP2, SP3, and SP4, except for the first non-emission area NEA1 where the bank portion BA is disposed. For example, the second overcoat layer OC2 may include at least one second pattern portion OC2_P disposed in the emission areas EA1, EA2, EA3, and EA4, and a bank pattern portion OC2_BA disposed in the second non-emission area NEA2.

The emission areas EA1, EA2, EA3, and EA4 may correspond to regions in which light is emitted in the respective subpixels SP1, SP2, SP3, and SP4. For example, each subpixel SP1, SP2, SP3, and SP4 may include the light emitting device ED configured by overlapping the pixel electrode AE, the emission layer EL, and the common electrode CE, and the emission areas EA1, EA2, EA3, and EA4 may correspond to the light emitting devices ED of the respective subpixels SP1, SP2, SP3, and SP4. For example, the emission areas EA1, EA2, EA3, and EA4 may correspond to areas of the pixel electrodes AE patterned and disposed on the first overcoat layer OC1 and the second overcoat layer OC2.

The emission areas EA1, EA2, EA3, and EA4 may include first to fourth emission areas EA1, EA2, EA3, and EA4 that emit light of different colors. For example, the emission areas EA1, EA2, EA3, and EA4 may overlap at least one color filter CF1, CF3, and CF4, and thus may emit light of different colors through the color filters.

The at least one color filter CF1, CF3, and CF4 may emit light of different colors. For example, the at least one color filter CF1, CF3, and CF4 may be formed of organic materials that transmit light of different colors. The at least one color filter CF1, CF3, and CF4 may include a first color filter CF1 that transmits red light, a third color filter CF3 that transmits blue light, and a fourth color filter CF4 that transmits green light.

The first emission area EA1 of the first subpixel SP1 may emit red light through the first color filter CF1, the second emission area EA2 of the second subpixel SP2 may emit white light through no color filter or through a color filter that transmits white light, the third emission area EA3 of the third subpixel SP3 may emit blue light through the third color filter CF3, and the fourth emission area EA4 of the fourth subpixel SP4 may emit green light through the fourth color filter CF4, but implementations of the present disclosure are not limited thereto.

According to one implementation of the present disclosure, the plurality of subpixels SP1, SP2, SP3, and SP4 may include the first overcoat layer OC1 and the second overcoat layer OC2 disposed on a substrate 111. For example, the first overcoat layer OC1 and the second overcoat layer OC2 may be disposed to overlap the emission areas EA1, EA2, EA3, and EA4. The light emitting device ED may be disposed on the first overcoat layer OC1 and the second overcoat layer OC2.

Among the plurality of subpixels SP1, SP2, SP3, and SP4, the first and second overcoat layers OC1 and OC2 may be disposed on corresponding the color filters CF1, CF3, and CF4 in the first, third, and fourth subpixels SP1, SP3, and SP4, where the color filters CF1, CF3, and CF4 are provided. In addition, in the second subpixel SP2 among the plurality of subpixels SP1, SP2, SP3, and SP4, where no color filter is provided, the first and second overcoat layers OC1 and OC2 may be disposed on the at least one insulating layer BF or PAS. For example, the light emitting devices ED corresponding to the first, third, and fourth subpixels SP1, SP3, and SP4 and the light emitting device ED corresponding to the second subpixel SP2 may have different heights. For example, the light emitting devices ED corresponding to the first, third, and fourth subpixels SP1, SP3, and SP4 may have greater heights than the light emitting device ED corresponding to the second subpixel SP2 by a height corresponding to that of the color filters CF1, CF3, and CF4, but implementations of the present disclosure are not limited thereto.

As shown in FIGS. 4 to 6, the display panel 110 according to one implementation of the present disclosure may include the substrate 111, the plurality of data lines DL1, DL2, DL3, and DL4, the at least one first power voltage line DVL, the reference voltage line RVL, the at least one insulating layer BF or PAS, the at least one color filter CF1, CF3, and CF4, the first overcoat layer OC1, the second overcoat layer OC2, the reflective layer RP, the pixel electrode AE, the emission layer EL, and the common electrode CE.

At least one voltage signal line may be disposed on the substrate 111. For example, the plurality of data lines DL1, DL2, DL3, and DL4, the at least one first power voltage line DVL, and the reference voltage line RVL may be disposed on the substrate 111. For example, the plurality of data lines DL1, DL2, DL3, and DL4, the at least one first power voltage line DVL, and the reference voltage line RVL may be formed of the same material in the same layer as a light blocking layer disposed in the pixel circuits CA1, CA2, CA3, and CA4, but implementations of the present disclosure are not limited thereto.

The at least one insulating layer BF and PAS may be disposed on the substrate 111. The at least one insulating layer BF and PAS may be disposed on the pixel circuits CA1, CA2, CA3, and CA4, and may include a buffer layer BF and a passivation layer PAS. For example, the buffer layer BF may be disposed on the substrate 111. The buffer layer BF may be configured to cover at least one voltage signal line and a light-shielding layer on the substrate 111. At least one thin film transistor and the passivation layer PAS may be disposed on the buffer layer BF. For example, between the buffer layer BF and the passivation layer PAS, a gate insulating layer and an interlayer insulating layer interposed between, or covering, an active layer, a gate electrode, and source/drain electrodes of the at least one thin film transistor may further be included, but implementations of the present disclosure are not limited thereto. For example, the at least one insulating layer BF and PAS may be formed as a single layer or multilayer including inorganic insulating materials such as silicon oxide SiO_{X}, silicon nitride SiN_{X}, and aluminum oxide Al₂O₃, but implementations of the present disclosure are not limited thereto.

The at least one color filter CF1, CF3, and CF4 may be disposed on the at least one insulating layer BF and PAS. For example, the at least one color filter CF1, CF3, and CF4 may be disposed on the passivation layer PAS. The at least one color filter CF1, CF3, and CF4 may be disposed to correspond to the first, third, and fourth subpixels SP1, SP3, and SP4 among the first to fourth subpixels SP1, SP2, SP3, and SP4. The at least one color filter CF1, CF3, and CF4 may have the first overcoat layer OC1 and the second overcoat layer OC2 disposed thereon. In addition, among the first to fourth subpixels SP1, SP2, SP3, and SP4, a color filter may not be disposed in the second subpixel SP2. For example, the first overcoat layer OC1 and the second overcoat layer OC2 may be disposed on the passivation layer PAS corresponding to the second subpixel SP2.

On the at least one insulating layer BF and PAS, a portion of the at least one color filter CF1, CF3, and CF4 and the second overcoat layer OC2 may be disposed in the second non-emission area NEA2 between adjacent subpixels SP1, SP2, SP3, and SP4. For example, in the second non-emission area NEA2 between the first subpixel SP1 and the second subpixel SP2, a portion of the first color filter CF1 and the second overcoat layer OC2 covering the first color filter CF1 may be disposed. In addition, in the second non-emission area NEA2 between the second subpixel SP2 and the third subpixel SP3, a portion of the third color filter CF3 and the second overcoat layer OC2 covering the third color filter CF3 may be disposed. Furthermore, in the second non-emission area NEA2 between the third subpixel SP3 and the fourth subpixel SP4, portions of the third color filter CF3 and the fourth color filter CF4 may be disposed to overlap or be spaced apart from each other, and the second overcoat layer OC2 covering the third and fourth color filters CF3 and CF4 may be disposed.

In the emission areas EA1, EA2, EA3, and EA4 of the respective subpixels SP1, SP2, SP3, and SP4, the first overcoat layer OC1, the second overcoat layer OC2, and the reflective layer RP may be disposed on the at least one insulating layer BF and PAS or on the at least one color filter CF1, CF3, and CF4. For example, the first overcoat layer OC1, the second overcoat layer OC2, and the reflective layer RP may be disposed on corresponding the color filters CF1, CF3, and CF4 of the first, third, and fourth subpixels SP1, SP3, and SP4. In addition, the first overcoat layer OC1, the second overcoat layer OC2, and the reflective layer RP may be disposed on at least one insulating layer BF or PAS of a second subpixel SP2.

According to one implementation of the present disclosure, the first overcoat layer OC1 may be disposed on the at least one insulating layer BF and PAS or on the at least one color filter CF1, CF3, and CF4. The first overcoat layer OC1 may have a sloped side surface OC1_S3 so that the first overcoat layer OC1 has a positive taper structure in which a width of the first overcoat layer OC1 increases closer toward a substrate 111. In addition, the reflective layer RP may be formed on the sloped side surface OC1_S3 of the first overcoat layer OC1. The second overcoat layer OC2 may be formed in contact with the first overcoat layer OC1 so as to cover the reflective layer RP. For example, the reflective layer RP may be disposed between the first overcoat layer OC1 and the second overcoat layer OC2. The first overcoat layer OC1 and the second overcoat layer OC2 may have different heights at a portion where they contact each other. For example, a height of the first overcoat layer OC1 may be greater than a height of the second overcoat layer OC2. In the emission areas EA1, EA2, EA3, and EA4 of the respective subpixels SP1, SP2, SP3, and SP4, the light emitting device ED may be disposed on the first overcoat layer OC1 and the second overcoat layer OC2.

The first overcoat layer OC1 may include a first surface OC1_S1 contacting the light emitting device ED and a second surface OC1_S2 opposite to the first surface OC1_S1. For example, a width D1 of the first surface OC1_S1 of the first overcoat layer OC1 may be smaller than a width D2 of the second surface OC1_S2 of the first overcoat layer OC1.

The first overcoat layer OC1 according to one implementation of the present disclosure may include a plurality of first pattern portions OC1_P having a trapezoidal shape with the first surface OC1_S1, the second surface OC1_S2, and the sloped side surface OC1_S3. For example, the sloped side surfaces OC1_S3 of the plurality of first pattern portions OC1_P may form an angle (a) of 45° to 70° with respect to the second surface OC1_S2. The reflective layer RP may be formed on the sloped side surfaces OC1_S3 of the plurality of first pattern portions OC1_P.

The second overcoat layer OC2 may include a first surface OC2_S1 contacting the light emitting device ED and a second surface OC2_S2 opposite to the first surface OC2_S1. For example, a width d1 of the first surface OC2_S1 of the second overcoat layer OC2 may be greater than a width d2 of the second surface OC2_S2 of the second overcoat layer OC2. The second overcoat layer OC2 may include at least one second pattern portion OC2_P formed between adjacent ones of the plurality of first pattern portions OC1_P. The at least one second pattern portion OC2_P may be formed to cover the reflective layer RP disposed on the sloped side surfaces OC1_S3 of the plurality of first pattern portions OC1_P. A height H2 of the first surface OC2_S1 of the second overcoat layer OC2 may be lower than a height H1 of the first surface OC1_S1 of the first overcoat layer OC1. For example, the height H2 of the first surface OC2_S1 of the at least one second pattern portion OC2_P may be lower than the height H1 of the first surface OC1_S1 of the plurality of first pattern portions OC1_P.

The reflective layer RP may be disposed on the sloped side surfaces OC1_S3 of the plurality of first pattern portions OC1_P. The reflective layer RP may provide a plurality of reflection structures between the light emitting device ED and the substrate 111. For example, the reflective layer RP may be formed of a metal material having high reflectivity, such as a laminated structure of aluminum and titanium (Ti/Al/Ti), a laminated structure of aluminum and ITO (ITO/Al/ITO), a silver (Ag) alloy, a laminated structure of an Ag alloy and ITO (ITO/Ag alloy/ITO), a molybdenum titanium (MoTi) alloy, or a laminated structure of a MoTi alloy and ITO (ITO/MoTi alloy/ITO). The Ag alloy may be an alloy of silver (Ag), palladium (Pd), and copper (Cu). The MoTi alloy may be an alloy of molybdenum (Mo) and titanium (Ti). In addition, the reflective layer RP may be formed of a semi-transmissive conductive material such as magnesium (Mg), silver (Ag), or an alloy of magnesium (Mg) and silver (Ag), but implementations of the present disclosure are not limited thereto.

The light emitting device ED may overlap each of the emission areas EA1, EA2, EA3, and EA4 and may be disposed on the first overcoat layer OC1 and the second overcoat layer OC2. For example, the light emitting device ED may be disposed on the plurality of first pattern portions OC1_P of the first overcoat layer OC1 and on the at least one second pattern portion OC2_P of the second overcoat layer OC2. The light emitting device ED may have a groove shape formed by a step difference between the plurality of first pattern portions OC1_P and the at least one second pattern portion OC2_P. The light emitting device ED may include the pixel electrode (first electrode or anode electrode) AE, the emission layer (or organic emission layer) EL, and the common electrode (second electrode or cathode electrode) CE corresponding to each of the emission areas EA1, EA2, EA3, and EA4.

The pixel electrode AE may be disposed on the first and second overcoat layer OC1 and OC2. The pixel electrode AE may be patterned on the first and second overcoat layer OC1 and OC2 to define the respective emission areas EA1, EA2, EA3, and EA4. An area of the patterned pixel electrode AE may correspond to the respective emission areas EA1, EA2, EA3, and EA4. The pixel electrode AE may be formed of a transparent metal material or a semi-transmissive metal material. For example, the pixel electrode AE may be formed of a transparent conductive material (TCO, Transparent Conductive Material) that can transmit light, such as indium tin oxide (ITO) or indium zinc oxide (IZO). The pixel electrode AE may be formed of a semi-transmissive conductive material such as magnesium (Mg), silver (Ag), or an alloy of magnesium (Mg) and silver (Ag). For example, the pixel electrode AE formed of a semi-transmissive metal material may have improved light-extraction efficiency by a micro-cavity. The pixel electrode AE may be the anode electrode of the light emitting device ED.

The emission layer EL may be disposed on the pixel electrode AE. In addition, the emission layer EL may be a common layer formed over all of the plurality of subpixels SP1, SP2, SP3, and SP4. The emission layer EL may be disposed on the first overcoat layer OC1 and the second overcoat layer OC2. For example, the emission layer EL may be disposed on a portion of the first surface OC1_S1 and the sloped side surface OC1_S3 of the first overcoat layer OC1 and on the first surface OC2_S1 of the second overcoat layer OC2. The emission layer EL may include a hole transporting layer, an emission material layer, and an electron transporting layer. For example, when a voltage is applied to the pixel electrode AE and the common electrode CE, holes and electrons move to the emission layer EL through the hole transporting layer and the electron transporting layer, respectively, and may recombine in the emission layer EL to emit light. For example, the emission layer EL may be a white emission layer that emits white light.

The emission layer EL according to an implementation of the present disclosure may include two or more emission layers to emit white light. For example, the emission layer EL may be configured as a tandem structure including a first emission layer and a second emission layer vertically stacked to emit white light by mixing first light and second light. For example, the emission layer EL may also be configured with three or four vertically stacked emission layers, but implementations of the present disclosure are not limited thereto.

The common electrode CE may be disposed on the emission layer EL. In addition, the common electrode CE may be a common layer formed across all of the plurality of subpixels SP1, SP2, SP3, and SP4. The common electrode CE may be disposed on the first overcoat layer OC1 and the second overcoat layer OC2. For example, the common electrode CE may be disposed on a portion of the first surface OC1_S1 and the sloped side surface OC1_S3 of the first overcoat layer OC1 and on the first surface OC2_S1 of the second overcoat layer OC2. The common electrode CE may be disposed on the pixel electrode AE and the emission layer EL, which contact each other, to form the emission areas EA1, EA2, EA3, and EA4. For example, the common electrode CE may be formed of a metal material having high reflectivity, such as a laminated structure of aluminum and titanium (Ti/Al/Ti), a laminated structure of aluminum and ITO (ITO/Al/ITO), a silver (Ag) alloy, a laminated structure of an Ag alloy and ITO (ITO/Ag alloy/ITO), a molybdenum titanium (MoTi) alloy, or a laminated structure of a MoTi alloy and ITO (ITO/MoTi alloy/ITO). The Ag alloy may be an alloy of silver (Ag), palladium (Pd), and copper (Cu). The MoTi alloy may be an alloy of molybdenum (Mo) and titanium (Ti). The common electrode CE may serve as a cathode electrode of the light emitting device ED.

According to one example of the present disclosure, as shown in FIGS. 4 and 5, the second overcoat layer OC2 may have a convex upper surface. For example, the at least one second pattern portion OC2_P of the second overcoat layer OC2 may have the convex first surface OC2_S1 in which a center portion CL is higher than a peripheral portion. For instance, a height h2 of the center portion CL of the first surface OC2_S1 of the at least one second pattern portion OC2_P may be greater than a height h1 of the peripheral portion, thereby forming a convex surface. In addition, an upper surface of the first overcoat layer OC1 may be formed as a flat surface. For example, the plurality of first pattern portions OC1_Pof the first overcoat layer OC1 may have the flat first surface OC1_S1 that is higher than the first surface OC2_S1 of the at least one second pattern portion OC2_P. The area of the first surface OC1_S1 of the plurality of first pattern portions OC1_P may be larger than the area of the first surface OC2_S1 of the at least one second pattern portion OC2_P. Accordingly, the light emitting device ED according to one example of the present disclosure may have a groove shape of a convex lens type formed by a shape difference between the plurality of first pattern portions OC1_P and the at least one second pattern portion OC2_P. Thus, the second overcoat layer OC2 configured to have the convex lens shape may form a light extraction path in which light emitted from the light emitting device ED is reflected by the common electrode CE arranged in the convex lens shape and condensed in a downward direction.

According to another example of the present disclosure, as shown in FIG. 6, the second overcoat layer OC2 may have a flat upper surface. For example, the at least one second pattern portion OC2_P of the second overcoat layer OC2 may have the flat first surface OC2_S1. In addition, an upper surface of the first overcoat layer OC1 may also be a flat surface. For example, the plurality of first pattern portions OC1_P of the first overcoat layer OC1 may have the flat first surface OC1_S1 that is higher than the first surface OC2_S1 of the at least one second pattern portion OC2_P. The area of the first surface OC1_S1 of the plurality of first pattern portions OC1_P may be larger than the area of the first surface OC2_S1 of the at least one second pattern portion OC2_P. Accordingly, the light emitting device ED according to another example of the present disclosure may have a groove shape formed by a step difference between the plurality of first pattern portions OC1_P and the at least one second pattern portion OC2_P. Thus, the second overcoat layer OC2 configured to have the flat surface may form a light extraction path in which light emitted from the light emitting device ED is reflected by the common electrode CE arranged in a flat shape and vertically directed downward.

Accordingly, the display panel 110 according to one implementation of the present disclosure can improve light extraction efficiency by allowing light confined in a waveguide mode inside the light emitting device ED to be reflected downward and extracted by the common electrode CE arranged in a groove shape formed by a step difference between the plurality of first pattern portions OC1_P and the at least one second pattern portion OC2_P, or in a convex lens-type groove shape formed by a shape difference between the plurality of first pattern portions OC1_P and the at least one second pattern portion OC2_P. In addition, the display panel 110 according to one implementation of the present disclosure can further improve light extraction efficiency by allowing light confined in a glass guide mode within the substrate 111 to be reflected downward and extracted by the reflective layer RP disposed between the light emitting device ED and the substrate 111.

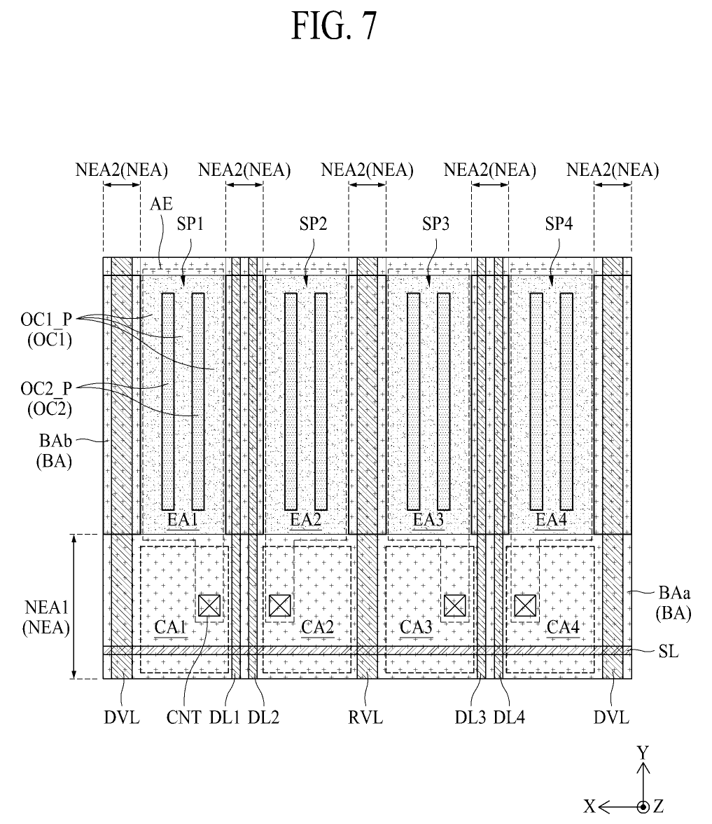

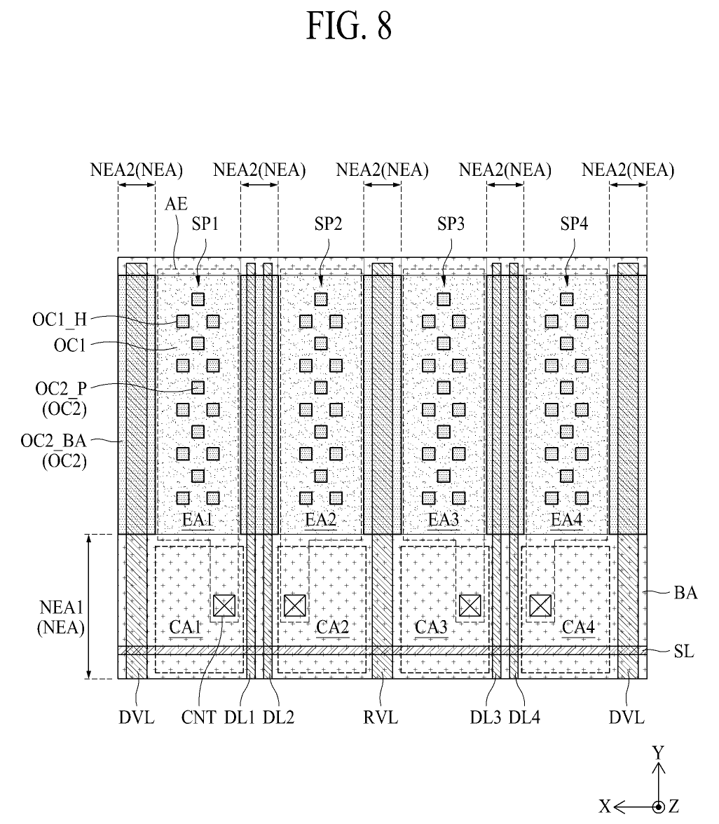

FIG. 7 illustrates a plurality of subpixels in a display panel according to another implementation of the present disclosure. FIG. 8 illustrates a plurality of subpixels in a display panel according to another implementation of the present disclosure. FIG. 7 illustrates an implementation in which a configuration of the second non-emission area NEA2 is modified in the light emitting display apparatus described with reference to FIGS. 1 to 6, and FIG. 8 illustrates an implementation in which configurations of the emission areas EA1, EA2, EA3, and EA4 are modified in the light emitting display apparatus described with reference to FIGS. 1 to 6. In the following description referring to FIGS. 7 and 8, the same reference numerals as in FIGS. 1 to 6 are used for the same components, and redundant description for the identical configurations is omitted or given briefly except for the modified configurations.

As shown in FIG. 7, the second overcoat layer OC2 according to another implementation of the present disclosure may be disposed in the emission areas EA1, EA2, EA3, and EA4. The second overcoat layer OC2 may be disposed within the emission areas EA1, EA2, EA3, and EA4 and may not be disposed in the second non-emission area NEA2.

According to another implementation of the present disclosure, the bank portion BA may include a first bank portion BAa and a second bank portion BAb. For example, the first bank portion BAa may be disposed in the first non-emission area NEA1, and the second bank portion BAb may be disposed in the second non-emission area NEA2. For example, the first bank portion BAa and the second bank portion BAb may be formed of the same material or of different materials. For example, the first bank portion BAa and the second bank portion BAb may be formed of an organic layer such as acryl resin, epoxy resin, phenolic resin, polyamide resin, or polyimide resin. For example, the first bank portion BAa and the second bank portion BAb may be formed of the same material and may be formed by the same process.

According to another implementation of the present disclosure, the first bank portion BAa and the second bank portion BAb may be black banks including at least one of a light-absorbing material or a black material. For example, the first bank portion BAa and the second bank portion BAb may include an insulating light-absorbing material such as black resin or graphite.

According to another implementation of the present disclosure, the first bank portion BAa and the second bank portion BAb may be formed of different materials. For example, the first bank portion BAa may be a transparent bank formed of an organic layer such as acryl resin, epoxy resin, phenolic resin, polyamide resin, or polyimide resin, and the second bank portion BAb may be a black bank including an insulating light-absorbing material such as black resin or graphite, but implementations of the present disclosure are not limited thereto.

As shown in FIG. 8, the first overcoat layer OC1 according to another implementation of the present disclosure may include a plurality of groove pattern portions OC1_H. For example, the plurality of groove pattern portions OC1_H of the first overcoat layer OC1 may penetrate the first surface OC1_S1 and the second surface OC1_S2 of the first overcoat layer OC1, and may be formed in an inverted trapezoidal shape having a sloped side surface OC1_S3. The reflective layer RP may be formed on the sloped side surface OC1_S3 of the plurality of groove pattern portions OC1_H.

The second overcoat layer OC2 may include a plurality of second pattern portions OC2_P formed in the plurality of groove pattern portions OC1_H. For example, the plurality of second pattern portions OC2_P of the second overcoat layer OC2 may be formed in a manner of being filled within the plurality of groove pattern portions OC1_H.

According to another implementation of the present disclosure, the plurality of groove pattern portions OC1_H and the plurality of second pattern portions OC2_P may be arranged at regular intervals on a plane and may be disposed in a grid pattern or a chess pattern, but implementations of the present disclosure are not limited thereto.

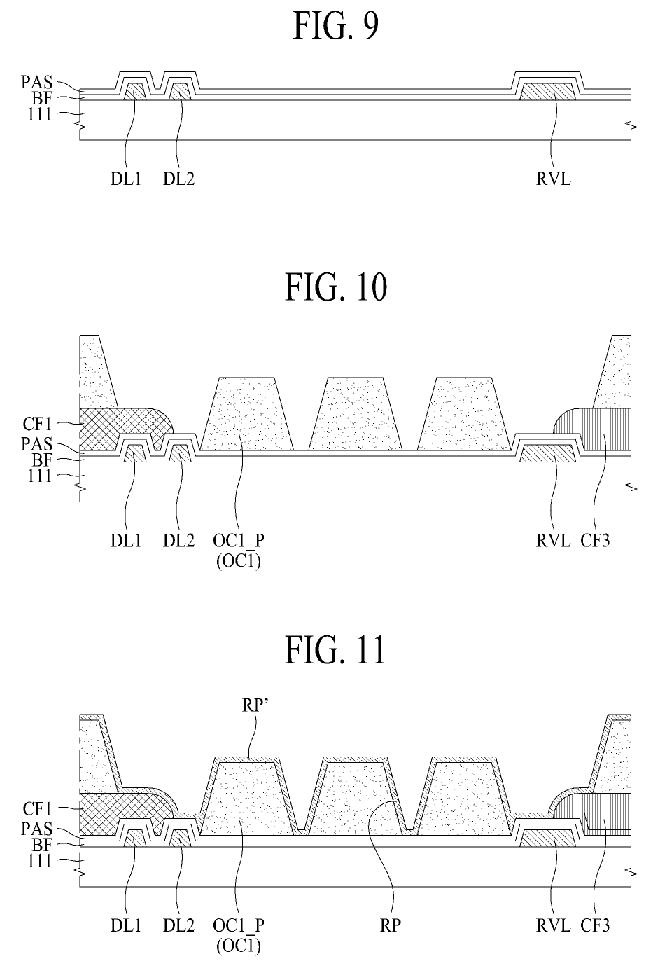

FIGS. 9 to 16 illustrate a method of manufacturing a display panel according to one implementation of the present disclosure. FIGS. 9 to 16 illustrate a method for manufacturing the light emitting display apparatus described with reference to FIGS. 1 to 8. FIGS. 9 to 16 show a manufacturing method for a portion of the second subpixel SP2. In the following description, the same reference numerals as in FIGS. 1 to 8 are used, and redundant description is omitted or given briefly.

As shown in FIG. 9, the at least one voltage signal line may be patterned on the substrate 111, and the buffer layer BF may be formed over an entire surface of the substrate 111. The at least one voltage signal line may include the data line DL, the first power voltage line DVL, and the reference voltage line RVL. For example, the at least one voltage signal line may include the first and second data lines DL1 and DL2 and the reference voltage line RVL. The passivation layer PAS may be formed on the buffer layer BF.

As shown in FIG. 10, the at least one color filter CF1 and CF3 may be patterned on the passivation layer PAS. For example, the first color filter CF1 may be disposed on the passivation layer PAS corresponding to the first subpixel SP1, and the third color filter CF3 may be disposed on the passivation layer PAS corresponding to the third subpixel SP3. The first overcoat layer OC1 may be coated and patterned on the at least one color filter CF1 and CF3 and the passivation layer PAS. For example, the first overcoat layer OC1 may be patterned to form the plurality of first pattern portions OC1_P. Each of the first pattern portions OC1_P may have a sloped side surface so that the first pattern portions OC1_P has a positive taper structure in which a width of the first pattern portions OC1_P increases toward the substrate 111.

As shown in FIG. 11, a reflective layer RP′ may be formed on the plurality of first pattern portions OC1_P. For example, the reflective layer RP′ may be disposed along the sloped side surfaces of the plurality of first pattern portions OC1_P.

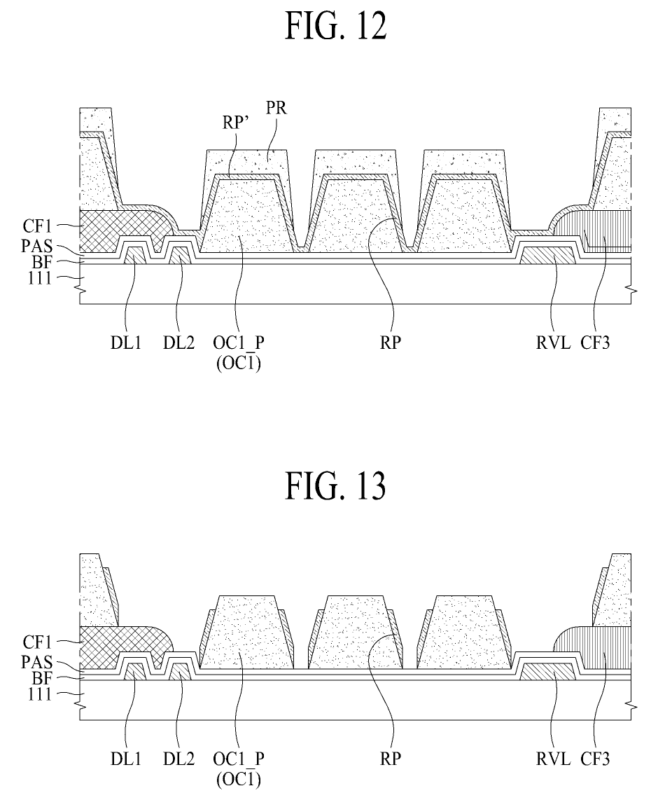

As shown in FIG. 12, a photoresist PR may be disposed on the reflective layer RP′.

As shown in FIG. 13, the reflective layer RP′ may be subjected to a first etching process using the photoresist PR as a mask, leaving only the reflective layers RP on the upper surfaces and sloped side surfaces of the plurality of first pattern portions OC1_P, and removing the reflective layer RP′ between the plurality of first pattern portions OC1_P.

The photoresist PR according to one implementation of the present disclosure may be a negative photoresist NPR. After the etching process, the photoresist PR may remain only on the upper surfaces of the plurality of first pattern portions OC1_P, and through a second exposure process, only the reflective layers RP on the sloped side surfaces of the plurality of first pattern portions OC1_P may remain, thereby patterning the reflective layer RP on the sloped side surfaces of the plurality of first pattern portions OC1_P.

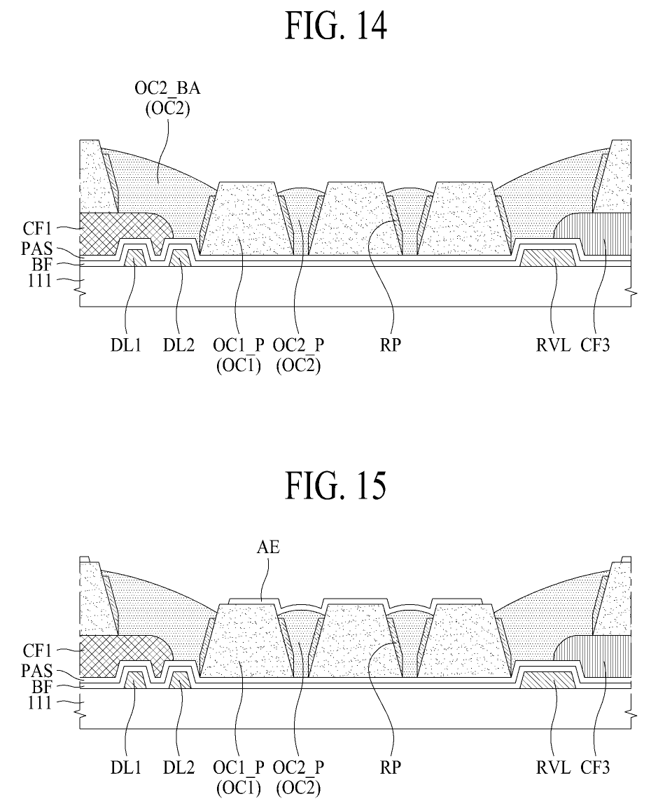

As shown in FIG. 14, the second overcoat layer OC2 may be coated and patterned between the plurality of first pattern portions OC1_P. For example, the second overcoat layer OC2 may be patterned to form the at least one second pattern portion OC2_P. The at least one second pattern portion OC2_P may be formed in contact with the plurality of first pattern portions OC1_P of the first overcoat layer OC1 to cover the reflective layer RP formed on the sloped side surfaces of the plurality of first pattern portions OC1_P. An upper surface of the at least one second pattern portion OC2_P may be formed as a flat surface or a convex surface having a center portion higher than a peripheral portion. For example, the at least one second pattern portion OC2_P may be formed in a convex shape by a heat treatment process or by using a half tone mask.

As shown in FIG. 15, the pixel electrode AE may be patterned on the first and second overcoat layers OC1 and OC2. The pixel electrode AE may be patterned to define the second emission area EA2. For example, the second emission area EA2 may correspond to an area of the pixel electrode AE patterned and disposed on the first and second overcoat layers OC1 and OC2. The pixel electrode AE may have a groove shape formed by a step difference between the plurality of first pattern portions OC1_P and the at least one second pattern portion OC2_P, or may have a groove shape of a convex lens type formed by a shape difference between the plurality of first pattern portions OC1_P and the at least one second pattern portion OC2_P.

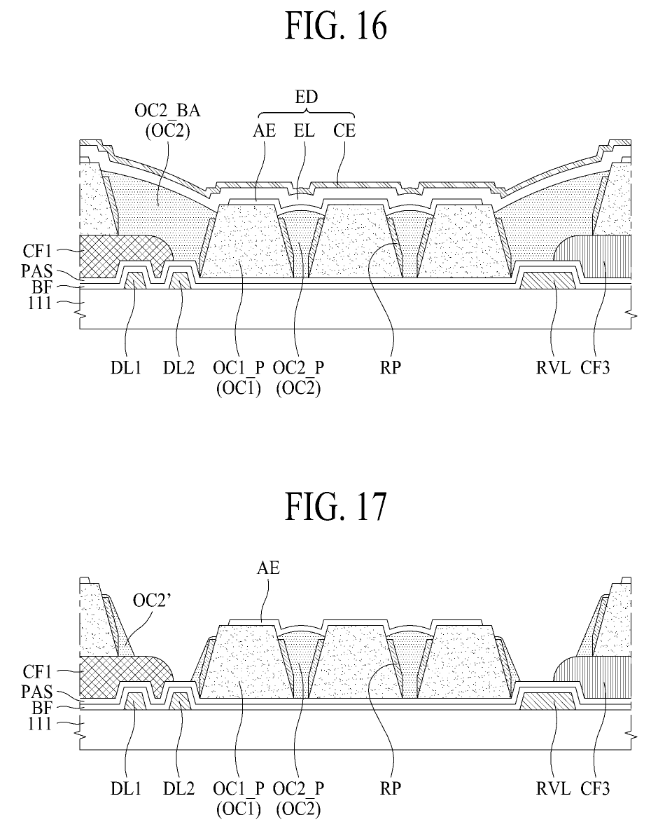

As shown in FIG. 16, the emission layer EL and the common electrode CE may be sequentially formed over the entire surface. The light emitting device ED including the pixel electrode AE, the emission layer EL, and the common electrode CE may have a groove shape of a convex lens type formed by a step difference and a shape difference between the plurality of first pattern portions OC1_P and the at least one second pattern portion OC2_P.

According to one implementation of the present disclosure, in the manufacturing method of the light emitting display apparatus, the reflective layer RP may be patterned on the sloped side surfaces of the first overcoat layer OC1 by performing a first etching process and a second exposure process using a single patterned photoresist layer, and a convex lens shape may be formed on an upper surface of the second overcoat layer OC2 through a heat treatment process. Accordingly, it is possible to manufacture the light emitting display apparatus capable of improving light extraction efficiency without increasing manufacturing processes and costs.

FIGS. 17 to 19 illustrate a method of manufacturing a display panel according to another implementation of the present disclosure. FIGS. 17 to 19 illustrate a method for manufacturing the light emitting display apparatus according to another implementation in which a configuration of the second non-emission area NEA2 is modified in the manufacturing method of the light emitting display apparatus described with reference to FIGS. 9 to 16. FIGS. 17 to 19 illustrate subsequent manufacturing processes following those shown in FIGS. 9 to 14.

As shown in FIG. 17, the second overcoat layer OC2 disposed in the second non-emission area NEA2 between adjacent subpixels may be etched and removed. The second overcoat layer OC2 may leave a residue pattern OC2′ in the second non-emission area NEA2 so as to cover the reflective layer RP disposed on the sloped side surface of the first overcoat layer OC1.

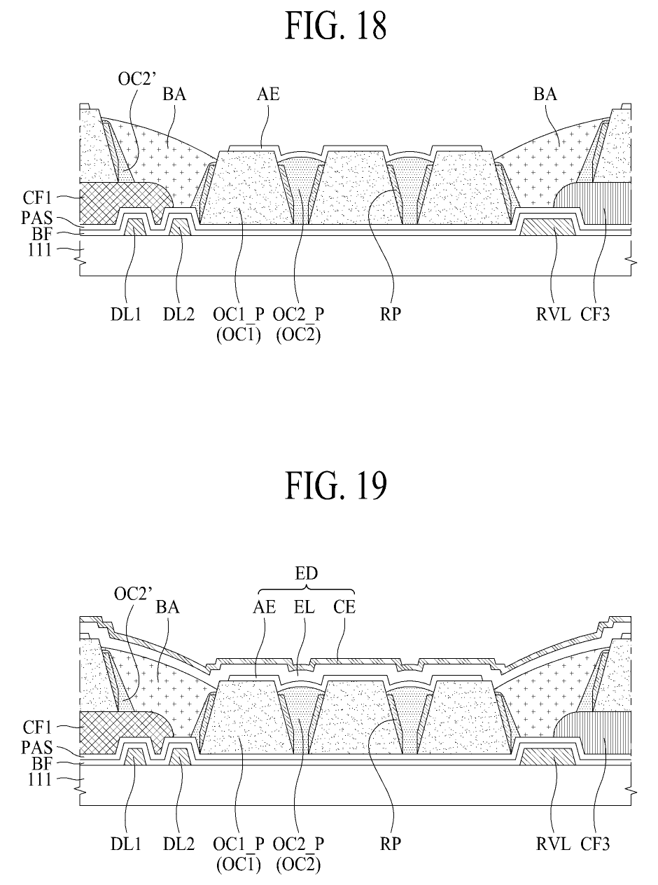

As shown in FIG. 18, the bank portion BA may be formed in the second non-emission area NEA2. For example, the bank portion BA may be formed of the same material as or a different material from the bank portion disposed in the first non-emission area NEA1. For example, the bank portion BA may be formed as a black bank including an insulating light-absorbing material such as black resin or graphite to prevent color mixing between adjacent subpixels, but implementations of the present disclosure are not limited thereto.

As shown in FIG. 19, the emission layer EL and the common electrode CE may be sequentially formed over the entire surface. The light emitting device ED including the pixel electrode AE, the emission layer EL, and the common electrode CE may have a groove shape of a convex lens type formed by a step difference and a shape difference between the plurality of first pattern portions OC1_P and the at least one second pattern portion OC2_P.

According to another implementation of the present disclosure, in the manufacturing method of the light emitting display apparatus, the reflective layer RP may be patterned on the sloped side surface of the first overcoat layer OC1 by performing a first etching process and a second exposure process using a single patterned photoresist layer, a convex lens shape may be formed on an upper surface of the second overcoat layer OC2 through a heat treatment process, and the bank portion BA may be formed in the first and second non-emission areas NEA1 and NEA2 through the same process. Accordingly, it is possible to manufacture a light emitting display apparatus capable of improving light extraction efficiency without increasing manufacturing processes and costs.

A light emitting display apparatus according to one or more example implementations of the present disclosure will be described below.

A light emitting display apparatus according to one or more implementations of the present disclosure may include a substrate including a plurality of subpixels, the substrate having an emission area and a non-emission area, a pixel circuit disposed in the non-emission area of the substrate, at least one insulating layer disposed on the pixel circuit, a first overcoat layer disposed on the at least one insulating layer, the first overcoat layer having a sloped side surface and configured with a positive taper structure in which a width of the first overcoat layer increases toward the substrate, a reflective layer formed on the sloped side surface of the first overcoat layer, a second overcoat layer contacting the first overcoat layer and covering the reflective layer, and a light emitting device disposed on the first overcoat layer and the second overcoat layer to overlap the emission area.

According to one or more implementations of the present disclosure, the reflective layer may be disposed between the first overcoat layer and the second overcoat layer.

According to one or more implementations of the present disclosure, the first overcoat layer and the second overcoat layer may have different heights at a portion where the first overcoat layer and the second overcoat layer contact each other.

According to one or more implementations of the present disclosure, a height of the first overcoat layer may be greater than a height of the second overcoat layer.

According to one or more implementations of the present disclosure, the first overcoat layer may include a first surface contacting the light emitting device and a second surface opposite to the first surface, and a width of the first surface may be smaller than a width of the second surface.

According to one or more implementations of the present disclosure, the first overcoat layer may include a plurality of first pattern portions having a trapezoidal shape with the first surface, the second surface, and the sloped side surface.

According to one or more implementations of the present disclosure, the sloped side surfaces of the plurality of first pattern portions may form an angle of 45° to 70° with respect to the second surface.

According to one or more implementations of the present disclosure, the second overcoat layer may include a first surface contacting the light emitting device and a second surface opposite to the first surface, and a width of the first surface may be greater than a width of the second surface.

According to one or more implementations of the present disclosure, a width of the first surface of the second overcoat layer may be smaller than a width of the first surface of the first overcoat layer.

According to one or more implementations of the present disclosure, a height of the first surface of the second overcoat layer may be lower than a height of the first surface of the first overcoat layer.

According to one or more implementations of the present disclosure, the second overcoat layer may include at least one second pattern portion formed between adjacent ones of the plurality of first pattern portions.

According to one or more implementations of the present disclosure, the first surface of the at least one second pattern portion may be formed as a flat surface.

According to one or more implementations of the present disclosure, the light emitting device may have a groove shape formed by a step difference between the plurality of first pattern portions and the at least one second pattern portion.

According to one or more implementations of the present disclosure, the first surface of the at least one second pattern portion may be formed as a convex surface having a center portion higher than a peripheral portion.

According to one or more implementations of the present disclosure, the light emitting device may have a groove shape of a convex lens type formed by a shape difference between the plurality of first pattern portions and the at least one second pattern portion.

According to one or more implementations of the present disclosure, the first overcoat layer may include a first surface contacting the light emitting device and a second surface contacting the at least one insulating layer, and the first overcoat layer may include a plurality of groove pattern portions, each of which penetrates the first surface and the second surface and has an inverted trapezoidal shape with a sloped side surface.

According to one or more implementations of the present disclosure, the second overcoat layer may include a plurality of second pattern portions formed in the plurality of groove pattern portions.

According to one or more implementations of the present disclosure, the light emitting display apparatus may further include a color filter disposed between the at least one insulating layer and the light emitting device and corresponding to at least some of the plurality of subpixels, the first overcoat layer and the second overcoat layer may be disposed on the color filter.

According to one or more implementations of the present disclosure, the plurality of subpixels may include a white subpixel in which the color filter is not disposed, and the first overcoat layer and the second overcoat layer may contact the at least one insulating layer in an area of the white subpixel.

According to one or more implementations of the present disclosure, the non-emission area may include a first non-emission area in which the pixel circuit is disposed and a second non-emission area between adjacent subpixels among the plurality of subpixels, the light emitting display apparatus may further include a bank portion disposed in the first non-emission area, the second overcoat layer or the bank portion may be disposed in the second non-emission area.

The above-described feature, structure, and effect of the present disclosure are included in at least one implementation of the present disclosure, but are not limited to only one implementation. Furthermore, the feature, structure, and effect described in at least one implementation of the present disclosure may be implemented through combination or modification of other implementations by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A light emitting display apparatus, comprising:
a substrate including a plurality of subpixels, the substrate having an emission area and a non-emission area;
a pixel circuit disposed in the non-emission area of the substrate;
at least one insulating layer disposed on the pixel circuit;
a first overcoat layer disposed on the at least one insulating layer, the first overcoat having a sloped side surface and configured with a positive taper structure in which a width of the first overcoat layer increases toward the substrate;
a reflective layer formed on the sloped side surface of the first overcoat layer;
a second overcoat layer contacting the first overcoat layer and covering the reflective layer; and
a light emitting device disposed on the first overcoat layer and the second overcoat layer and overlapping the emission area.

2. The light emitting display apparatus of claim 1, wherein the reflective layer is disposed between the first overcoat layer and the second overcoat layer.

3. The light emitting display apparatus of claim 1, wherein the first overcoat layer and the second overcoat layer have different heights at a portion where the first overcoat layer and the second overcoat layer contact each other.

4. The light emitting display apparatus of claim 3, wherein a height of the first overcoat layer is greater than a height of the second overcoat layer.

5. The light emitting display apparatus of claim 1, wherein the first overcoat layer includes a first surface contacting the light emitting device and a second surface opposite to the first surface, and a width of the first surface is smaller than a width of the second surface.

6. The light emitting display apparatus of claim 5, wherein the first overcoat layer includes a plurality of first pattern portions having a trapezoidal shape with the first surface, the second surface, and the sloped side surface.

7. The light emitting display apparatus of claim 6, wherein the sloped side surfaces of the plurality of first pattern portions form an angle of 45° to 70° with respect to the second surface.

8. The light emitting display apparatus of claim 6, wherein the second overcoat layer includes a first surface contacting the light emitting device and a second surface opposite to the first surface, and a width of the first surface is greater than a width of the second surface.

9. The light emitting display apparatus of claim 8, wherein a width of the first surface of the second overcoat layer is smaller than a width of the first surface of the first overcoat layer.

10. The light emitting display apparatus of claim 8, wherein a height of the first surface of the second overcoat layer is lower than a height of the first surface of the first overcoat layer.

11. The light emitting display apparatus of claim 10, wherein the second overcoat layer includes at least one second pattern portion formed between adjacent ones of the plurality of first pattern portions.

12. The light emitting display apparatus of claim 11, wherein the first surface of the at least one second pattern portion is formed as a flat surface.

13. The light emitting display apparatus of claim 12, wherein the light emitting device has a groove shape formed by a step difference between the plurality of first pattern portions and the at least one second pattern portion.

14. The light emitting display apparatus of claim 11, wherein the first surface of the at least one second pattern portion is formed as a convex surface having a center portion higher than a peripheral portion.

15. The light emitting display apparatus of claim 14, wherein the light emitting device has a groove shape of a convex lens type formed by a shape difference between the plurality of first pattern portions and the at least one second pattern portion.

16. The light emitting display apparatus of claim 1, wherein the first overcoat layer includes a first surface contacting the light emitting device and a second surface contacting the at least one insulating layer, and the first overcoat layer includes a plurality of groove pattern portions, each of which penetrates the first surface and the second surface and has an inverted trapezoidal shape with a sloped side surface.

17. The light emitting display apparatus of claim 16, wherein the second overcoat layer includes a plurality of second pattern portions formed in the plurality of groove pattern portions.

18. The light emitting display apparatus of claim 1, further comprising a color filter disposed between the at least one insulating layer and the light emitting device and corresponding to at least some of the plurality of subpixels,
wherein the first overcoat layer and the second overcoat layer are disposed on the color filter.

19. The light emitting display apparatus of claim 18, wherein the plurality of subpixels includes a white subpixel in which the color filter is not disposed, and
wherein the first overcoat layer and the second overcoat layer contact the at least one insulating layer in an area of the white subpixel.

20. The light emitting display apparatus of claim 1, wherein the non-emission area includes a first non-emission area in which the pixel circuit is disposed and a second non-emission area between adjacent subpixels among the plurality of subpixels,
wherein the light emitting display apparatus further comprises a bank portion disposed in the first non-emission area,
wherein the second overcoat layer or the bank portion is disposed in the second non-emission area.
